(19) United States
(12) Patent Application Publication
(10) Pub. No.: US 2004/0183614 A1
(43) Pub. Date: Sep. 23, 2004

(54) Frequency modulation using a zero hz vco

(76) Inventors: Jeroen Kuenen, ME Enschede (NL); Marcel Dekker, Hengelo (NL)

Correspondence Address: Stanley R Moore, Jenkens & Gilchrist, Suite 3200, 1445 Ross Avenue, Dallas, TX, 75202-4500, US

(21) Appl. No.: 10/474,276

(22) PCT Filed: Apr. 12, 2002
(86) PCT No.: PCT/SE02/00741

Related U.S. Application Data
(60) Provisional application No. 60/283,682, filed on Apr. 13, 2001.

(51) Int. Cl. H03C 3/00

(52) U.S. Cl. 332/117

(57) ABSTRACT

Method and system are disclosed for modulating a radio frequency carrier signal. The radio frequency carrier signal is modulated using a VCO running at a center frequency of 0 Hz. A baseband signal is used to adjust the overall frequency of the VCO. The output of the VCO is a complex baseband signal having in-phase and quadrature components. The in-phase and quadrature components of the baseband signal arc used to modulate the in-phase and quadrature components of the radio frequency carrier signal, respectively.

### BACKGROUND

1. Field of the Invention

The invention is related to electronics for radio transmitters and, in particular, to a method and system for modulating a radio frequency signal using a voltage controlled oscillator.

2. History of the Related Art

Modern radio communication systems use frequency modulation (FM) to transmit and receive information. In FM, a baseband signal containing the information to be transmitted is used to modulate a radio frequency carrier signal. The advantages of using FM are well-known and will not be described here. It is important, however, to maintain the frequency of the carrier signal at or very near a target or center frequency. Drifts or changes in the frequency of the carrier signal beyond a predefined tolerance will result in errors during recovery of the baseband signal.

A number of techniques exists for synthesizing a well-controlled carrier signal. One way to synthesize a carrier signal involves the use of a voltage controlled oscillator (VCO). FIG. 1 illustrates a basic example of a frequency synthesis system 100 that can be implemented using a VCO. The system 100 in FIG. 1 includes a phase detector 102, a summing node 104, and a VCO 106. The phase detector 102 generates an output signal that is combined with a baseband signal at the summing node 104. The output of the summing node 104 is then used to control the frequency of the VCO 106. The output signal from the VCO 106 is the carrier signal. This carrier signal is fed back to the phase detector 102 to form a closed loop. The phase detector 102 compares the frequency of the carrier signal with the frequency of a reference signal. If there is any difference between the two frequencies, the phase detector 102 adjusts its output signal so as to reduce or eliminate the difference. Such a feedback arrangement is referred to as a phase-locked loop (PLL) and usually results in a tightly controlled carrier signal.

A drawback of the feedback arrangement is that the phase detector 102 tends to counteract the modulation of the carrier signal frequency. In other words, the phase detector 102 sees the modulation of the carrier signal frequency as causing a drift or change away from the frequency of the reference signal. Accordingly, the phase detector 102 tries to adjust the carrier signal frequency back towards the target frequency.

One way to solve the above problem is to provide a switch 108 in the path of the closed loop. The switch 108 can be used to open the loop during modulation so that there is no feedback to the phase detector 102. With the loop open, the phase detector 102 does not try to adjust the carrier signal frequency, but simply maintains the last known frequency. A drawback of the open loop solution, however, is the frequency of the carrier signal may drift due to temperature effects, leakage, and other factors.

To avoid the open loop condition altogether during modulation, direct up-conversion of the baseband signal may be used, as shown in FIG. 2. The system 200 in FIG. 2 uses a synthesizer to synthesize the carrier signal. Because the system 200 is a direct up-conversion system (i.e., no intermediate frequency (IF)), complex up-converting is needed. Therefore, the output of the synthesizer 202 is converted by a quadrature generator 204 to a complex signal having in-phase (I) and quadrature (Q) components. Modulation is then performed on the I and Q components of the carrier signal, respectively. The modulation signal is provided by a conventional digital modulation generator 206. The input to the digital modulation generator 206 is a digital baseband signal. The digital modulation generator 206 converts the digital baseband signal to a complex signal having a digital I component and a digital Q component. The digital I and Q components are then converted by digital-to-analog converters 208 and 210 to analog I and Q components, respectively. The analog I and Q components are passed through low-pass filters 212 and 214, also called reconstruction filters, to remove any high frequency noise therefrom. Mixers 216 and 218 are used to mix (up-convert) the I and Q components of the baseband signal with the I and Q components of the carrier signal, respectively. The outputs of the mixers 216 and 218 are subsequently combined at a summing node 220 to produce the modulated carrier signal. Note that the combination of the mixers 216 and 218, the summing node 220, and the quadrature generator 204 form an image-reject mixer that rejects the image of the baseband signal in the transmitted signal.

Because the modulated carrier signal is not fed back to the synthesizer 202 in the arrangement of FIG. 2, the open loop modulation problem described above is avoided. Other drawbacks exist, however. For example, the use of components such as the digital modulation generator 206, digital-to-analog converters 208 and 210, and low-pass filters 212 and 214 increases the costs of the system 200. Moreover, converting the baseband signal from the digital domain to the analog domain gives rise to quantization errors. The quantization errors in the transmitted signal result in increased adjacent channel power emissions.

Therefore, it is desirable to be able to provide a way to modulate a radio frequency carrier signal that does not suffer the limitations and drawbacks of prior solutions. More specifically, it is desirable to be able to provide a radio frequency modulator that can avoid the open loop modulation condition, and that can do so without giving rise to digital quantization errors.

### SUMMARY OF THE INVENTION

The present invention is directed to a system and method for modulating a radio frequency carrier signal. The radio frequency carrier signal is modulated using a VCO running at a center frequency of 0 Hz. A baseband signal is used to adjust the overall frequency of the VCO. The output of the VCO is a complex baseband signal having I and Q components. The complex baseband signal is then used to modulate the radio frequency carrier signal. By operating the VCO at 0 Hz, the image of the baseband signal is shifted into the same transmitted channel as the desired signal. Therefore, the image does not reside at some other point in the frequency spectrum where rigorous requirements on spurious signals govern.

In general, in one aspect, the invention is directed to a system for modulating a frequency of a carrier signal. The system comprises a synthesizer configured to synthesize a radio frequency carrier signal having an in-phase component and a quadrature component. The system further comprises a 0 Hz oscillator configured to generate a modulation signal having an in-phase component and a quadrature component. Mixers are connected to the synthesizer and the 0 Hz oscillator. The mixers are configured to mix the in-phase and quadrature components of the carrier signal with the in-phase and quadrature components of the modulation signal, respectively.

In general, in another aspect, the invention is directed to a method of modulating a frequency of a carrier signal. The method comprises synthesizing a radio frequency carrier signal having an in-phase component and a quadrature component. The method further comprises generating a modulation signal using a 0 Hz oscillator. The modulation signal has an in-phase component and a quadrature component. The in-phase and quadrature components of the radio frequency carrier signal are then mixed with the in-phase and quadrature components of the modulation signal, respectively.

In general, in another aspect, the invention is directed to a method of generating a frequency modulated carrier signal. The method comprises providing a baseband signal, and generating a modulation signal centered at 0 Hz using the baseband signal. The method further comprises synthesizing a carrier signal, and up-converting the modulation signal directly to a frequency of the carrier signal.

### BRIEF DESCRIPTION OF THE DRAWINGS

A more complete understanding of the invention may be had by reference to the following detailed description when taken in conjunction with the accompanying drawings, wherein:

FIG. 1 illustrates an example of a prior art frequency modulation technique;

FIG. 2 illustrates another example of a prior art frequency modulation technique;

FIG. 3 illustrates a frequency modulation technique according to embodiments of the invention;

FIG. 4 illustrates a detailed view of a VCO used in the frequency modulation technique according to embodiments of the invention; and

FIG. 5 illustrates a method of generating a frequency modulated carrier signal according to embodiments of invention.

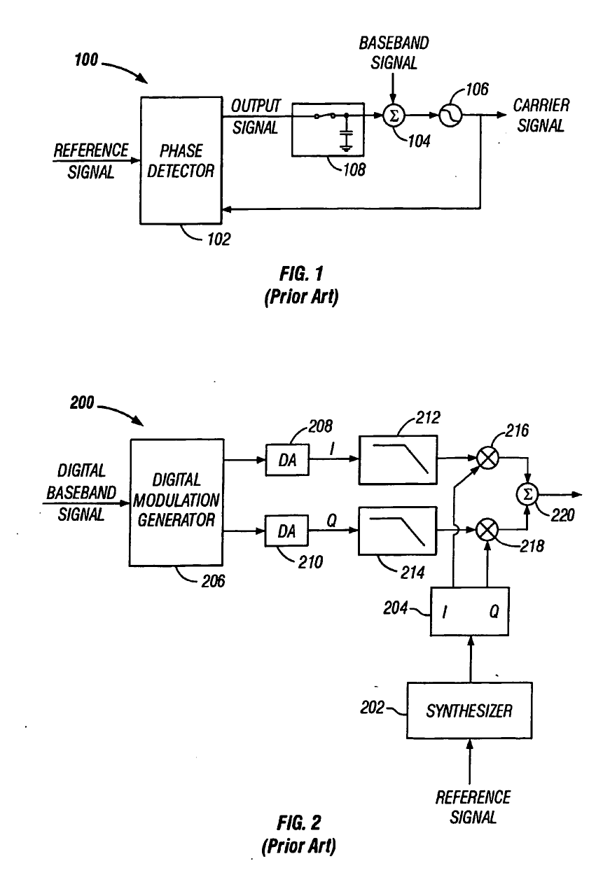

### DETAILED DESCRIPTION OF EXEMPLARY EMBODIMENTS

Following is a detailed description of the drawings wherein reference numerals for the same and similar elements are carried forward.

Embodiments of the invention provide a system and method for modulating a radio frequency carrier signal. A conventional frequency synthesizer is used to synthesize a radio frequency carrier signal. A VCO running at a center frequency of 0 Hz is then used to modulate the radio frequency carrier signal. The overall frequency of the VCO is controlled by the baseband signal. The VCO outputs a complex baseband signal that is centered around 0 Hz.

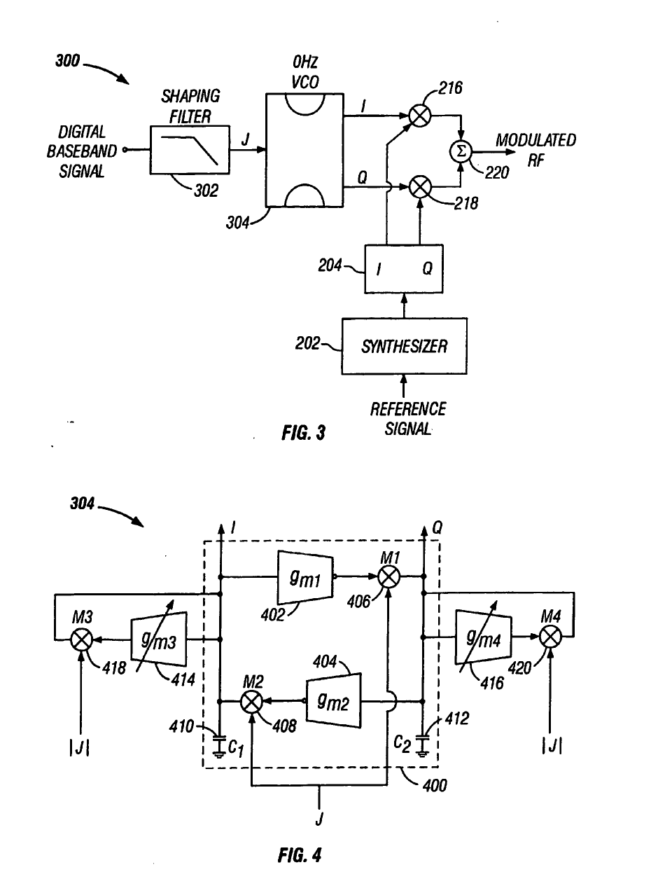

FIG. 3 illustrates a system 300 for modulating a radio frequency carrier signal according to some embodiments of the invention. The system 300 of FIG. 3 is similar to the system 200 of FIG. 2 in that the radio frequency carrier signal is synthesized using the synthesizer 202. The output of the synthesizer 202 is again converted by the quadrature generator 204 to a complex signal having I and Q components. The mixers 216 and 218 and the summing node 220 are also present. However, the digital modulation generator 206, the digital-to-analog converters 208 and 210, and the low-pass filters 212 and 214 have been replaced by a shaping filter 302 and a 0 Hz VCO 304.

A digital baseband signal is provided as the input signal to the shaping filter 302. The digital baseband signal is a bipolar signal (i.e., −1, 1), although in some embodiments it is possible to use a non-bipolar signal (i.e., 0, 1). The output of the shaping filter 302 is a smoothed, clearly defined digital baseband signal J. The shaped baseband signal J is then provided to the 0 Hz VCO 304. The baseband signal causes the VCO 304 to oscillate around 0 Hz by plus and minus the depth of the modulation frequency (e.g., ±155 KHz for a wireless network such as Bluetooth™). The result is a complex baseband signal having I and Q components. The I and Q components of the baseband signal are thereafter up-converted by the mixers 216 and 218 using the I and Q components of the carrier signal, respectively. The up-converted I and Q signals are subsequently combined in the summing node 220 to produce a modulated radio frequency carrier signal.

Note that the shaping filter 302 is an optional component and is used only as needed to shape the baseband signal. For example, the shaping filter 302 may be omitted in applications where the digital baseband signal may have already been smoothed and are not well defined square waves.

An exemplary implementation of the 0 Hz VCO 304 is shown in FIG. 4. As can be seen, the basic cell of the 0 Hz VCO is a two-integrator oscillator, implemented here using a gyrator cell 400. The gyrator cell 400 includes a first transconductor 402 and a second transconductor 404. The first and second transconductors 402 and 404 are typical transconductors such as bipolar junction or CMOS transconductors. Each transconductor 402 and 404 has a transconductance gₘ₁ and gₘ₂ associated therewith, respectively. The output of the first transconductor 402 generates the Q component of the complex baseband signal through a first multiplier 406 connected thereto. The output of the second transconductor 404 provides the I component of the complex baseband signal through a second multiplier 408 connected thereto. Note that the output of the first transconductor 402 needs to be inverted in accordance with well-known Nyquist principles.

Each multiplier 406 and 408 has a multiplication factor M1 and M2 associated therewith, respectively. The multiplication factors M1 and M2 are controlled by the baseband signal input J to the multipliers 406 and 408. A first capacitor 410 and a second capacitor 412 are connected between ground and the output of the first transconductor 402 and the output of the second transconductor 404, respectively. The capacitors 410 and 412 help to set the frequency of each transconductor 402 and 404, as discussed below.

In operation, the frequency for the first and second transconductors 402 and 404 can be expressed as follows:

$$\begin{matrix}{ϖ}_{1} = M1 \sqrt{\frac{{g}_{m1} {g}_{m2}}{{C}_{1} {C}_{2}}} & ( 1 ) \\ {ϖ}_{2} = M2 \sqrt{\frac{{g}_{m1} {g}_{m2}}{{C}_{1} {C}_{2}}} & ( 2 )\end{matrix}$$

where ωₓ is the angular frequency, gₘₓ is the transconductance of the respective transconductors 402 and 404, and Cₓ is the capacitance of the respective capacitors 410 and 412. Mₓ is the multiplication factor of the respective multipliers 406 and 408 and can be expressed as follows:

Mₓ=αJ (3)

where α is a constant that can be selected as needed for the application.

From Equations (1)-(3), it is seen that the frequency of the first and second transconductors 402 and 404 can be made negative if their respective multiplication factors Mₓ is negative. Thus, in some embodiments, four-quadrant multipliers are used for the first and second multipliers 406 and 408. Four-quadrant multipliers are a type of multiplier that can accept bipolar signals and, therefore, may result in a negative multiplication factor. This arrangement allows the frequency of the 0 Hz VCO to swing between plus and minus the depth of the modulation frequency. An advantage of letting the VCO swing around 0 Hz is that the image of the up-converted baseband signal is shifted into the same transmitted channel as the desired signal. Therefore, the image does not reside at some other point in the frequency spectrum where rigorous requirements on spurious signals govern.

In some embodiments, a mechanism may be provided to control the amplitude of the oscillations. In the example of FIG. 4, a third transconductor 414 and a fourth transconductor 416 are provided to control the oscillation amplitudes of the first and second transconductors 402 and 404. The outputs of the third and fourth transconductors 414 and 416 are connected to the outputs of the first and second transconductors 402 and 404 through a third multiplier 418 and a fourth multiplier 420. The third and fourth multipliers 418 and 420 have multiplication factors M3 and M4 that are controlled by the magnitude of the baseband signal |J| in accordance with Equation (3).

The third and fourth transconductors 414 and 416 have transconductances that are inversely dependent on the signal strength of the output signals from the first and second transconductors 402 and 404. The higher the output signals from the first and second transconductors 402 and 404, the lower the transconductance gₘ₃ and gₘ₄ of the third and fourth transconductors 414 and 416. This dependency is indicated by the symbol of a transconductor with an arrow drawn through it. The result of the inverse dependency is the oscillation amplitudes of the first and second transconductors 402 and 404 are kept from becoming too large.

Note that the third and fourth multipliers 418 and 420 do not have any influence on the frequency of the first and second transconductors 402 and 404, but only on the oscillation amplitudes thereof Therefore, by controlling the multiplication factors M3 and M4 using the signal |J|, the oscillation amplitudes of the first and second transconductors 402 and 404 are kept constant for all frequencies. To prevent instability, a negative multiplication factor for the third and fourth multipliers 418 and 420 must be avoided. Thus, the magnitude, or absolute value, of the signal J is used to control the third and fourth multipliers 418 and 420.

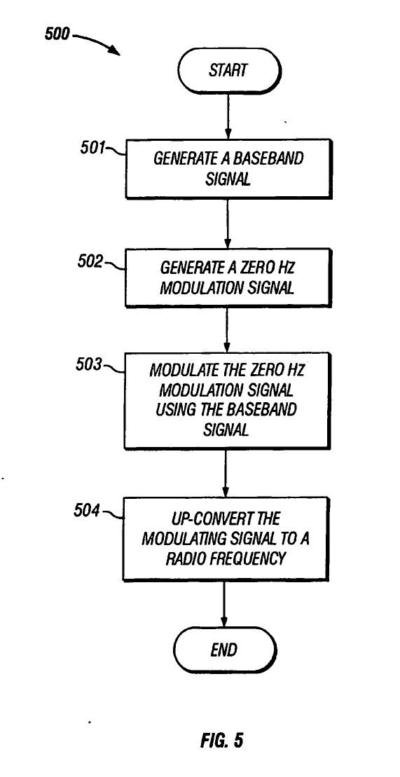

Referring now to FIG. 5, a method 500 of generating a frequency modulated carriers signal is shown. The method 500 begins in step 501 where a baseband signal is generated. The baseband signal may be a digital baseband signal that, in some cases, is also a bipolar digital baseband signal. In step 502, a 0 Hz modulating signal is generated using, for example, the 0 Hz VCO described with respect to FIG. 4. In step 503, the digital baseband signal is used to modulate the 0 Hz modulating signal. The resulting modulation signal is a complex signal that swings around 0 Hz by plus and minus the frequency of the baseband signal. In step 504, the modulation signal is up-converted directly to the frequency of the carrier signal. Up-conversion may be performed by mixing the complex components of the modulation signal with the complex components of the carriers signal, then combining the complex components of the mixed signal.

As demonstrated by the foregoing, embodiments of the invention provide a system and method for modulating a radio frequency carrier signal. While a limited number of embodiments have been disclosed herein, those of ordinary skill in the art will recognize that variations and modifications from the described embodiments may be derived without departing from the scope of the invention. Accordingly, the appended claims are intended to cover all such variations and modifications as falling within the scope of the invention.

What is claimed is:

1. A method of modulating a frequency of a carrier signal, comprising:
synthesizing a radio frequency carrier signal having an in-phase component and a quadrature component;
generating a modulation signal using a 0 Hz oscillator, said modulation signal having an in-phase component and a quadrature component; and
mixing said in-phase and quadrature components of said radio frequency carrier signal with said in-phase and quadrature components of said modulation signal, respectively.

2. The method according to claim 1, wherein said 0 Hz oscillator is a voltage controlled oscillator.

3. The method according to claim 1, further comprising combining said mixed in-phase and quadrature components.

4. The method according to claim 1, wherein said mixing step further comprises mixing said in-phase and quadrature components using image-reject mixers.

5. The method according to claim 1, wherein said step of generating said modulation signal includes controlling said 0 Hz oscillator using a digital baseband signal.

6. The method according to claim 5, wherein said digital baseband signal is a bipolar digital baseband signal.

7. The method according to claim 6, wherein said step of generating said modulation signal further includes controlling a gyrator of said 0 Hz oscillator using said digital baseband signal.

8. The method according to claim 7, wherein said step of controlling includes applying said digital baseband signal to a first transconductor and a second transconductor of said gyrator.

9. The method according to claim 8, further comprising multiplying the outputs of said first and second transconductors by a first multiplication factor and a second multiplication factor, respectively.

10. The method according to claim 9, further comprising controlling said first and second multiplication factors using said digital baseband signal.

11. The method according to claim 1, further comprising maintaining an amplitude of said generated modulation signal at a substantially constant level.

12. A system for modulating a frequency of a carrier signal, comprising:
a synthesizer configured to a synthesize a radio frequency carrier signal having an in-phase component and a quadrature component;
a 0 Hz oscillator configured to generate a modulation signal having an in-phase component and a quadrature component; and
mixers connected to said synthesizer and said 0 Hz oscillator, said mixers configured to mix said in-phase and quadrature components of said carrier signal with said in-phase and quadrature components of said modulation signal, respectively.

13. The system according to claim 12, further comprising a summing node configured to combine said mixed in-phase and quadrature components.

14. The system according to claim 12, wherein said 0 Hz oscillator is a voltage controlled oscillator.

15. The system according to claim 12, wherein said 0 Hz oscillator is configured to receive a digital baseband signal and to generate said modulation signal using said digital baseband signal.

16. The system according to claim 15, wherein said digital modulation signal is a bipolar digital modulation signal.

17. The system according to claim 16, wherein said 0 Hz oscillator is implemented using a gyrator.

18. The system according to claim 17, wherein said gyrator includes a first transconductor and a second transconductor, an output of said first transconductor connected to an input of said second transconductor via a first multiplier, and an output of said second transconductor connected to an input of said first transconductor via a second multiplier.

19. The system according to claim 18, wherein said first and second multipliers are four-quadrant multipliers.

20. The system according to claim 12, further comprising a third transconductor and a fourth transconductor connected to said first transconductor and said second transconductor, respectively, and configured to maintain an amplitude of said generated modulation signal substantially constant.

21. A method of generating a frequency modulated carrier signal, comprising:
providing a baseband signal;
generating a modulation signal centered at 0 Hz using said baseband signal;
synthesizing a carrier signal; and
up-converting said modulation signal directly to a frequency of said carrier signal.

22. The method according to claim 21, wherein said step of generating a modulation signal centered at 0 Hz results in said baseband signal and an image of said baseband signal residing in one channel.

23. The method according to claim 21, wherein said modulation signal centered at 0 Hz is generated using a voltage controlled oscillator.

24. The method according to claim 23, wherein said baseband signal is a digital baseband signal, and said voltage controlled oscillator is controlled using said digital baseband signal.

25. The method according to claim 24, wherein said digital baseband signal is a bipolar digital baseband signal.

26. The method according to claim 21, further comprising maintaining an amplitude of said modulation signal at a substantially constant level.

27. The method according to claim 21, wherein said step of up-converting is performed using image-reject mixers.
